(19) United States
(12) Patent Application Publication
(10) Pub. No.: US 2023/0380219 A1
(43) Pub. Date: Nov. 23, 2023

(54) DISPLAY APPARATUS AND METHOD OF MANUFACTURING THE SAME

(71) Applicant: Samsung Display Co., Ltd., Yongin-si (KR)

(72) Inventor: Jiyoon Kim, Yongin-si (KR)

(73) Assignee: Samsung Display Co., Ltd., Yongin-si (KR)

(21) Appl. No.: 18/119,969

(22) Filed: Mar. 10, 2023

(30) Foreign Application Priority Data
May 17, 2022 (KR) 10-2022-0060445
Jul. 5, 2022 (KR) 10-2022-0082699

(51) Int. Cl. H10K 59/122; H10K 59/12

(52) U.S. Cl. CPC H10K 59/122; H10K 59/1201; H10K 59/35

(57) ABSTRACT

A display apparatus includes a display element including a pixel electrode, an emission layer including a light emitting material, and an opposite electrode, a first bank layer including a first opening exposing a center portion of the pixel electrode, a second bank layer disposed over the first bank layer and including a second opening overlapping the first opening, and a residual sacrificial layer disposed between the first bank layer and the second bank layer and overlapping the second bank layer, wherein an upper surface of the second bank layer and an inner side surface of the second bank layer defining the second opening have lyophobicity.

### CROSS-REFERENCE TO RELATED APPLICATION(S)

This application claims priority, under 35 U.S.C. § 119, to and benefits of Korean Patent Application No. 10-2022-0060445, filed on May 17, 2022, and Korean Patent Application No. 10-2022-0082699, filed on Jul. 5, 2022, in the Korean Intellectual Property Office (KIPO), the entire contents of which are incorporated herein by reference.

### BACKGROUND

### 1. Technical Field

One or more embodiments relate to a display apparatus and a method of manufacturing the display apparatus.

### 2. Description of the Related Art

In general, a display apparatus includes a plurality of pixels that emit light to display an image based on an electrical signal. A pixel of an organic light emitting display (OLED) apparatus includes an organic light emitting diode as a display element. The organic light emitting diode includes a pixel electrode, an emission layer, and an opposite electrode. The emission layer of the organic light emitting diode may be formed by discharging ink including a light emitting material onto the pixel electrode.

### SUMMARY

However, in such a display apparatus of the related art and a method of manufacturing the display apparatus, there is a problem in that it is difficult to uniformly form the thickness of an emission layer of an organic light emitting diode. One or more embodiments include a display apparatus for displaying a high-quality image by being improved in the thickness uniformity of an emission layer and a method of manufacturing the display apparatus. However, these problems are merely examples and the scope of the disclosure is not limited thereto.

However, embodiments of the disclosure are not limited to those set forth herein. The above and other embodiments will become more apparent to one of ordinary skill in the art to which the disclosure pertains by referencing the detailed description of the disclosure given below.

According to one or more embodiments, a display apparatus includes a display element including a pixel electrode, an emission layer including a light emitting material, and an opposite electrode, a first bank layer including a first opening exposing a center portion of the pixel electrode, a second bank layer disposed over the first bank layer and including a second opening overlapping the first opening, and a residual sacrificial layer disposed between the first bank layer and the second bank layer and overlapping the second bank layer, wherein an upper surface of the second bank layer and an inner side surface of the second bank layer defining the second opening have lyophobicity.

In an embodiment, an inner side surface of the residual sacrificial layer may be disposed between an inner side surface of the first bank layer defining the first opening and the inner side surface of the second bank layer defining the second opening, and a boundary area of the emission layer may be disposed on the inner side surface of the residual sacrificial layer or the inner side surface of the first bank layer adjacent to the inner side surface of the residual sacrificial layer.

In an embodiment, the inner side surface of the first bank layer may have lyophilicity.

In an embodiment, an upper surface of the pixel electrode may have lyophilicity.

In an embodiment, a lower surface of the second bank layer contacting the residual sacrificial layer may have lyophilicity.

In an embodiment, the pixel electrode may include a plurality of pixel electrodes spaced apart from each other in a first direction, the first opening may include a plurality of first openings respectively overlapping the plurality of pixel electrodes, and the second opening may have a line shape extending in the first direction to overlap the plurality of first openings.

In an embodiment, the emission layer may continuously extend in the first direction.

In an embodiment, the pixel electrode may include a plurality of pixel electrodes spaced apart from each other in a first direction, and the first opening and the second opening may include a plurality of first openings and a plurality of second openings respectively overlapping the plurality of pixel electrodes.

In an embodiment, the emission layer may include a plurality of emission layers respectively overlapping the plurality of pixel electrodes.

In an embodiment, a thickness of the first bank layer may be in a range of about 200 nm to about 500 nm.

In an embodiment, a thickness of the second bank layer may be in a range of about 500 nm to about 1 μm.

In an embodiment, the residual sacrificial layer may include a tungsten oxide (WOₓ), a molybdenum oxide (MoOₓ), or a mixture thereof.

According to one or more embodiments, a method of manufacturing a display apparatus includes forming a pixel electrode over a substrate, forming a first bank layer including a first opening exposing a center portion of the pixel electrode, forming a sacrificial layer on the first bank layer, forming a second bank layer including a second opening overlapping the first opening on the sacrificial layer, performing a plasma treatment on a front surface of the substrate where the second bank layer is disposed, forming a residual sacrificial layer by removing the sacrificial layer exposed through the second opening, and forming an emission layer by discharging ink including a light emitting material onto the pixel electrode.

In an embodiment, an inner side surface of the residual sacrificial layer may be disposed between an inner side surface of the first bank layer defining the first opening and an inner side surface of the second bank layer defining the second opening, and an outer side surface of the ink including the light emitting material may be disposed on the inner side surface of the residual sacrificial layer or the inner side surface of the first bank layer adjacent to the inner side surface of the residual sacrificial layer.

In an embodiment, in the performing of the plasma treatment, an upper surface of the second bank layer, an inner side surface of the second bank layer, and an upper surface of the sacrificial layer exposed through the second opening may have lyophobicity.

In an embodiment, the sacrificial layer may include a tungsten oxide (WOₓ), a molybdenum oxide (MoOₓ), or a mixture thereof.

In an embodiment, a thickness of the sacrificial layer may be in a range of about 20 nm to about 50 nm.

In an embodiment, an inner side surface of the first bank layer and an upper surface of the pixel electrode may have lyophilicity.

In an embodiment, the pixel electrode may include a plurality of pixel electrodes spaced apart from each other in a first direction, the first opening may include a plurality of first openings respectively overlapping the plurality of pixel electrodes, and the second opening may have a line shape extending in the first direction to overlap the plurality of first openings.

In an embodiment, in the forming of the emission layer, the ink including the light emitting material may be discharged in the first direction, and the emission layer may continuously extend in the first direction.

In an embodiment, the pixel electrode may include a plurality of pixel electrodes spaced apart from each other in a first direction, and the first opening and the second opening may include a plurality of first openings and a plurality of second openings respectively overlapping the plurality of pixel electrodes.

In an embodiment, in the forming of the emission layer, the emission layer may include a plurality of emission layers respectively overlapping the plurality of pixel electrodes.

Other aspects, features, and advantages other than those described above will become apparent from the accompanying drawings, the appended claims, and the detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view illustrating a display apparatus according to an embodiment;

FIG. 2 is a schematic diagram of an equivalent circuit of a pixel included in a display apparatus according to an embodiment;

FIG. 3A is a schematic cross-sectional view illustrating a display apparatus according to an embodiment;

FIG. 3B is a cross-sectional view illustrating a display apparatus according to an embodiment;

FIG. 4 is a schematic plan view illustrating a display apparatus according to an embodiment;

FIG. 5 is a schematic cross-sectional view illustrating a cross-section of the display apparatus taken along line I-I′ in FIG. 4;

FIG. 6 is a schematic cross-sectional view illustrating a cross-section of the display apparatus taken along line II-II′ in FIG. 4;

FIG. 7 is a schematic plan view illustrating a display apparatus according to an embodiment;

FIG. 8 is a cross-sectional view illustrating a cross-section of the display apparatus taken along line III-III′ in FIG. 7;

FIG. 9 is a schematic cross-sectional view illustrating a cross-section of the display apparatus taken along line IV-IV′ in FIG. 7; and

FIGS. 10 to 16 are schematic cross-sectional views sequentially illustrating a method of manufacturing a display apparatus according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Herein, display apparatuses may be apparatuses displaying images and may be portable mobile apparatuses such as game machines, multimedia apparatuses, or ultra-compact PCs. Display apparatuses described below may include liquid crystal displays, electrophoretic displays, organic light emitting displays, inorganic EL displays (inorganic light emitting displays), field emission displays, surface-conduction electron-emitter displays, quantum dot displays, plasma displays, and cathode ray displays. Hereinafter, an organic light emitting display apparatus will be described as an example of as a display apparatus according to an embodiment; however, such various display apparatuses as described above may be used in embodiments.

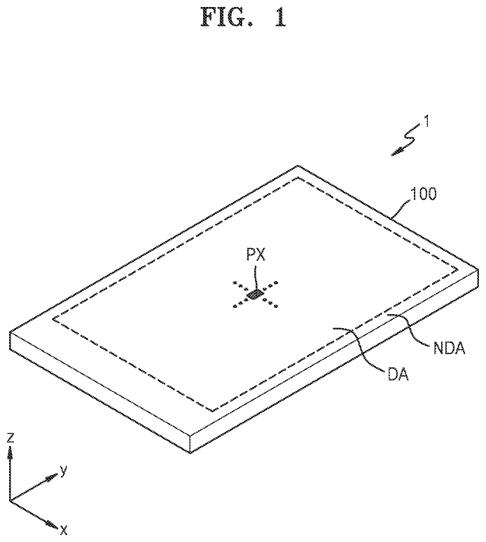

FIG. 1 is a schematic perspective view illustrating a display apparatus 1 according to an embodiment.

Referring to FIG. 1, the display apparatus 1 may include a display area DA and a non-display area NDA over a substrate 100.

The display area DA may display an image. Pixels PX, which are two-dimensionally arranged on a plane, may be arranged in the display area DA. Each pixel PX may be each of subpixels emitting lights of different colors. For example, each pixel PX may be any one of a red subpixel, a green subpixel, and a blue subpixel. The display apparatus 1 may display an image by using the light emitted from the pixels PX.

The non-display area NDA may be an area that does not display an image, and the pixels PX are not arranged in the non-display area NDA. The non-display area NDA may surround (e.g., entirely surround) the display area DA. A driver, a power line, or the like for providing an electrical signal (or power) to the pixels PX may be arranged in the non-display area NDA. The non-display area NDA may include a pad unit that is an area to which an electronic device, a printed circuit board, or the like may be electrically connected.

The display area DA may have a polygonal shape. For example, the display area DA may have a rectangular shape in which a horizontal length is greater than a vertical length as illustrated in FIG. 1. In another example, the display area DA may have a square shape. In another example, the display area DA may have various shapes such as an elliptical shape or a circular shape.

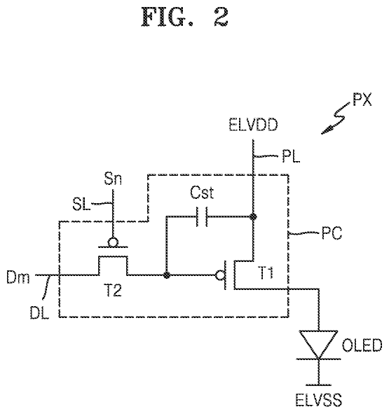

FIG. 2 is a schematic diagram of an equivalent circuit of a pixel PX included in a display apparatus according to an embodiment.

Referring to FIG. 2, the pixel PX may include a pixel circuit PC and a display element, for example, an organic light emitting diode OLED, connected to the pixel circuit PC. The pixel circuit PC may include a first thin film transistor T1, a second thin film transistor T2, and a storage capacitor Cst. Each pixel PX may emit, for example, red, green, or blue light or red, green, blue, or white light from the organic light emitting diode OLED.

For example, the second thin film transistor T2 (e.g., a switching thin film transistor) may be connected to a scan line SL and a data line DL and may transmit a data voltage or a data signal Dm input from the data line DL to the first thin film transistor T1 according to a switching voltage or a switching signal Sn, which is input from the scan line SL. The storage capacitor Cst may be connected to the second thin film transistor T2 and a driving voltage line PL and may store a voltage corresponding to the difference between a voltage received from the second thin film transistor T2 and a first power voltage ELVDD supplied to the driving voltage line PL.

For example, the first thin film transistor T1 (e.g., a driving thin film transistor) may be connected to the driving voltage line PL and the storage capacitor Cst and may control a driving current flowing from the driving voltage line PL through the organic light emitting diode OLED in response to a voltage value stored in the storage capacitor Cst. The organic light emitting diode OLED may emit light at a certain brightness according to the driving current. An opposite electrode (e.g., a cathode) of the organic light emitting diode OLED may be supplied with a second power voltage ELVSS.

FIG. 2 illustrates that the pixel circuit PC includes two thin film transistors and one storage capacitor; however, in other embodiments, the number of thin film transistors and the number of storage capacitors may be variously modified according to the design of the pixel circuit PC.

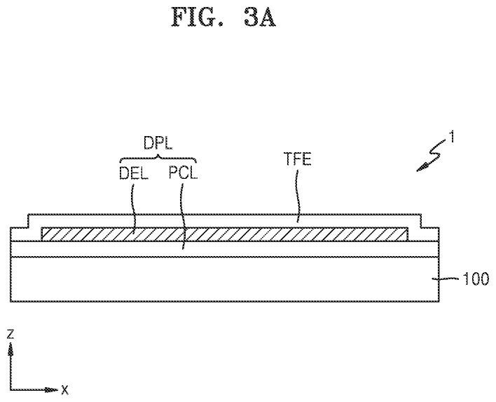

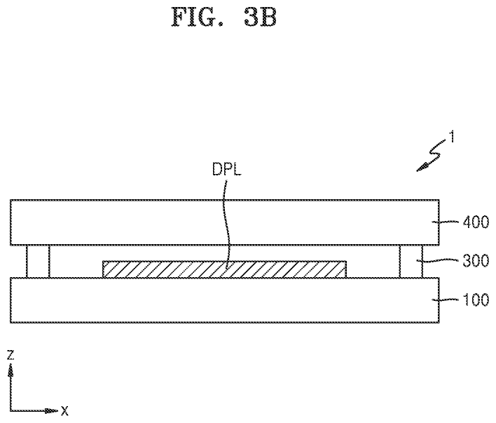

FIG. 3A is a schematic cross-sectional view illustrating a display apparatus 1 according to an embodiment. FIG. 3B is a schematic cross-sectional view illustrating a display apparatus 1 according to an embodiment.

Referring to FIG. 3A, a display layer DPL and a thin film encapsulation layer TFE may be included over a substrate 100 of the display apparatus 1. The display layer DPL may include a pixel circuit layer PCL including a pixel circuit and insulating layers, and a display element layer DEL disposed over the pixel circuit layer PCL and including display elements.

The substrate 100 may include glass, metal, or polymer resin. The polymer resin may include, for example, polyethersulphone, polyacrylate, polyetherimide, polyethylene naphthalate, polyethylene terephthalate, polyphenylene sulfide, polyarylate, polyimide, polycarbonate, cellulose acetate propionate, or any mixture thereof. The substrate 100 may be variously modified such as having a multilayer structure including two layers including the above polymer resin and a barrier layer arranged between the two layers and including an inorganic material such as silicon oxide (SiOₓ), silicon nitride (SiNₓ), or silicon oxynitride (SiON).

The display element layer DEL may include display elements, for example, organic light emitting diodes. The pixel circuit layer PCL may include insulating layers and pixel circuits electrically connected to the organic light emitting diodes. For example, the pixel circuit layer PCL may include transistors, storage capacitors, and insulating layers arranged therebetween.

The display elements may be covered by an encapsulation member such as a thin film encapsulation layer TFE. The thin film encapsulation layer TFE may include at least one inorganic encapsulation layer and at least one organic encapsulation layer covering the display element layer DEL. The inorganic encapsulation layer may include an inorganic insulating material such as aluminum oxide (Al₂O₃), titanium oxide (TiO₂), tantalum oxide (Ta₂O₅), hafnium oxide (HfO₂), zinc oxide (ZnO), silicon oxide (SiOₓ), silicon nitride (SiNₓ), or silicon oxynitride (SiON). The organic encapsulation layer may include a polymer-based material. The polymer-based material may include acryl-based resin, epoxy-based resin, polyimide, polyethylene, and the like. In an embodiment, the organic encapsulation layer may include acrylate.

Referring to FIG. 3B, a display layer DPL and an encapsulation substrate 400 may be included over a substrate 100 of the display apparatus 1. An encapsulation member 300 may be arranged between the substrate 100 and the encapsulation substrate 400. The encapsulation substrate 400 may be a transparent member. The substrate 100 and the encapsulation substrate 400 may be coupled by the encapsulation member 300 such that an internal space between the substrate 100 and the encapsulation substrate 400 may be encapsulated. For example, a moisture absorbent, a filler, or the like may be positioned in the internal space. The encapsulation member 300 may include a sealant, and in another example, the encapsulation member 300 may include a material that is cured by laser. For example, the encapsulation member 300 may include frit. For example, the encapsulation member 300 may include urethane-based resin, epoxy-based resin, or acryl-based resin that is an organic sealant, or silicone that is an inorganic sealant. For example, urethane acrylate or the like may be used as the urethane-based resin. For example, butyl acrylate, ethylhexyl acrylate, or the like may be used as the acryl-based resin. Moreover, the encapsulation member 300 may include a material that is cured by heat.

In some embodiments, a display element layer DEL may be covered by the encapsulation substrate 400 and the encapsulation member 300 of FIG. 3B together with the thin film encapsulation layer TFE of FIG. 3A.

A touch electrode layer may be disposed over the thin film encapsulation layer TFE and/or the encapsulation substrate 400, and an optical functional layer may be disposed over the touch electrode layer. The touch electrode layer may obtain or sense coordinate information according to an external input, for example, a touch event. The optical functional layer may reduce the reflectance of light (e.g., external light) incident from the outside toward the display apparatus 1. In another example, the optical functional layer may improve the color purity of light emitted from the display apparatus 1. In an embodiment, the optical functional layer may include a phase retarder and/or a polarizer. The phase retarder may be a film type or a liquid crystal coating type and may include a λ/2 phase retarder and/or a λ/4 phase retarder. The polarizer may be a film type or a liquid crystal coating type. The film type may include a stretched synthetic resin film, and the liquid crystal coating type may include liquid crystals arranged in a certain arrangement. The phase retarder and the polarizer may further include a protection film.

In another example, the optical functional layer may include a black matrix and color filters. The color filters may be arranged based on the color of light emitted from each of the pixels of the display apparatus 1. Each of the color filters may include a red, green, or blue pigment or dye. In another example, each of the color filters may further include quantum dots in addition to the above pigment or dye. In another example, some of the color filters may not include the above pigment or dye and may include scattering particles such as titanium oxide.

An adhesive member may be arranged between the touch electrode layer and the optical functional layer. The adhesive member may include a general adhesive without limitation. In an embodiment, the adhesive member may include a pressure sensitive adhesive (PSA).

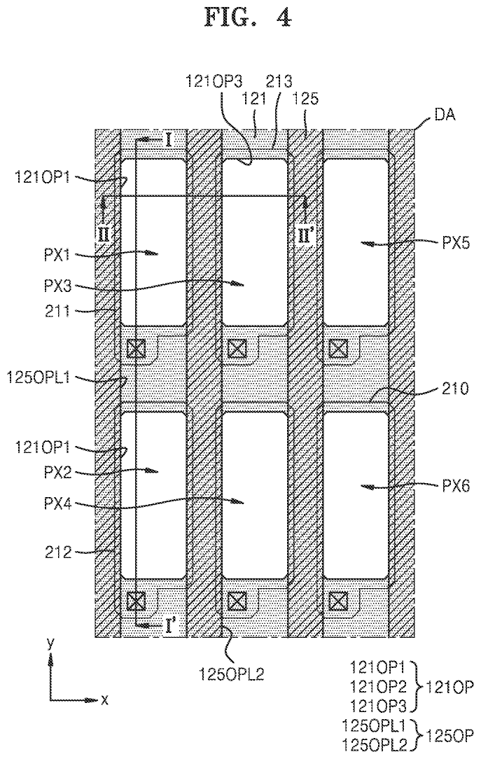

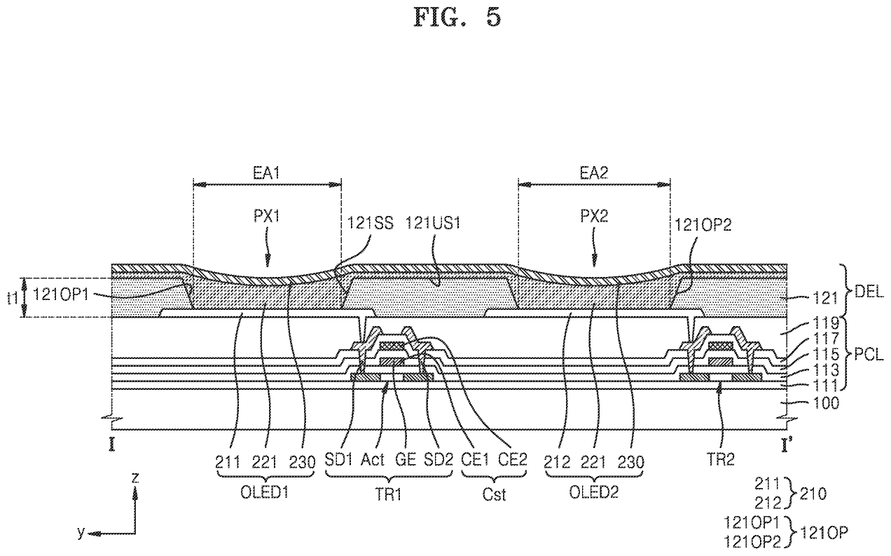

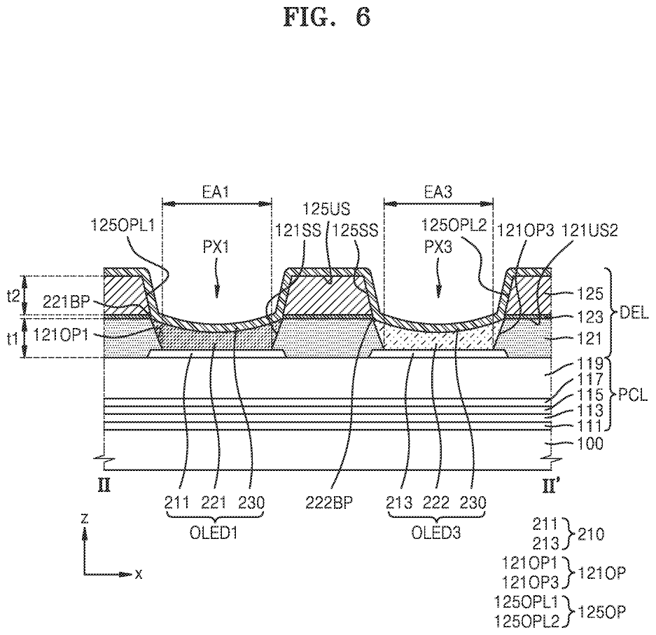

FIG. 4 is a schematic plan view illustrating a display apparatus according to an embodiment, FIG. 5 is a schematic cross-sectional view illustrating a cross-section of the display apparatus taken along line I-I′ in FIG. 4, and FIG. 6 is a schematic cross-sectional view illustrating a cross-section of the display apparatus taken along line II-II′ in FIG. 4.

Referring to FIG. 4, pixel electrodes 210, which are two-dimensionally arranged on a plane, may be arranged in a display area DA. The pixel electrodes 210 may be spaced apart from each other by a certain distance in a first direction (e.g., y-axis direction) and a second direction (e.g., x-axis direction). For example, a first pixel electrode 211 and a second pixel electrode 212 may be spaced apart from each other by a certain distance in the first direction (e.g., y-axis direction), and the first pixel electrode 211 and a third pixel electrode 213 may be spaced apart from each other by a certain distance in the second direction (e.g., x-axis direction).

In an embodiment, in a plan view, the pixel electrodes 210 may have various shapes such as a rectangular shape, a rhombic shape, a square shape, a circular shape, or an elliptical shape. In this regard, although FIG. 4 illustrates that the pixel electrodes 210 have a rectangular shape having a long side in the first direction (e.g., y-axis direction), embodiments are not limited thereto.

In an embodiment, the pixel electrode 210 may include a conductive material including molybdenum (Mo), aluminum (Al), copper (Cu), titanium (Ti), or the like and may include a single layer or multiple layers including the above material. In an embodiment, the pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In an embodiment, the pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or any compound thereof. In an embodiment, the pixel electrode 210 may have a multilayer structure of ITO/Ag/ITO.

In an embodiment, the surface of the pixel electrode 210 may have lyophilicity. Herein, the term “lyophilicity” may refer to a property that has excellent affinity for a certain solution, and as another property, the term “lyophobicity” may refer to a property that repels a certain solution and is not well infiltrated with a solution.

For example, as the certain solution has an excellent surface bonding force with respect to a lyophilic surface, the surface tension of the certain solution disposed on a lyophilic surface may decrease. The certain solution may have a low surface bonding force with respect to a lyophobic surface, and the surface tension of the certain solution disposed on a lyophobic surface may increase.

As the lyophilicity increases or as the surface tension decreases, a contact angle formed between a tangent line of the surface of the certain solution and a surface where the certain solution is positioned may decrease. For example, as the lyophobicity increases or as the surface tension increases, a contact angle between a certain surface and a surface where the certain solution is positioned may increase.

The certain solution may be ink including a light emitting material forming an emission layer or may be a solvent of ink. For example, the lyophilic surface may be a surface having a contact angle of about 5° or less with respect to a methyl benzonate (MeB) solution. For example, the lyophobic surface may be a surface having a contact angle of about 60° or more with respect to a methyl benzonate solution.

A first bank layer 121 may be arranged to cover the edge portion of each of the pixel electrodes 210. For example, the first bank layer 121 may include first openings 121OP exposing a center portion of each of the pixel electrodes 210. The first openings 121OP may be spaced apart from each other by a certain distance in the first direction (e.g., y-axis direction) and the second direction (e.g., x-axis direction) in a plan view, corresponding to (or overlapping) the pixel electrodes 210.

For example, the first bank layer 121 may include a (1-1)th opening 121OP1 exposing a center portion of the first pixel electrode 211, a (1-2)th opening 121OP2 exposing a center portion of the second pixel electrode 212, and a (1-3)th opening 121OP3 exposing a center portion of the third pixel electrode 213. The (1-1)th opening 121OP1 and the (1-2)th opening 121OP2 may be spaced apart from each other by a certain distance in the first direction (e.g., y-axis direction), and the (1-1)th opening 121OP1 and the (1-3)th opening 121OP3 may be spaced apart from each other by a certain distance in the second direction (e.g., x-axis direction).

In an embodiment, as illustrated in FIG. 4, the first opening 121OP may have a rectangular shape having a long side in the first direction (e.g., y-axis direction) like the pixel electrode 210 corresponding thereto. In an embodiment, the first opening 121OP may have a different shape than the pixel electrode 210 corresponding thereto. An emission area of a display element may be defined by the first opening 121OP, and hereinafter, the shape and position of a pixel may refer to the shape and position of an emission area of a display element.

In an embodiment, as illustrated in FIG. 4, the first bank layer 121 may have a grid shape in which a definition wall extending in the first direction (e.g., y-axis direction) and a definition wall extending in the second direction (e.g., x-axis direction) intersect each other.

The first bank layer 121 may include an inorganic insulating material or an organic insulating material. In an embodiment, the first bank layer 121 may include silicon oxide (SiOₓ), silicon nitride (SiNₓ), silicon oxynitride (SiON), or the like. In an embodiment, the first bank layer 121 may include an epoxy-based polymer, an acryl-based polymer, or a mixture thereof.

The surface of the first bank layer 121 may have lyophilicity. In another example, at least an upper surface of the first bank layer 121 exposed through a second opening 125OP and an inner side surface of the first bank layer 121 defining a first opening 121OP may have lyophilicity.

A second bank layer 125 may be positioned over the first bank layer 121. In an embodiment, the second bank layer 125 may include second openings 125OP exposing the center portions of the pixel electrodes 210 arranged in the first direction (e.g., y-axis direction). The second openings 125OP may have a line shape extending in the first direction (e.g., y-axis direction) and may overlap the first openings 121OP. In this regard, FIG. 4 illustrates that a line-shaped (2-1)th opening 125OPL1 exposes the center portions of the first pixel electrode 211 and the second pixel electrode 212 and overlaps the (1-1)th opening 121OP1 and the (1-2)th opening 121OP2. A line-shaped (2-2)th opening 125OPL2 may be spaced apart from the (2-1)th opening 125OPL1 by a certain distance in the second direction (e.g., x-axis direction).

In an embodiment, in a plan view, the second bank layer 125 may cover the edge portions of the pixel electrodes 210 extending in the first direction (e.g., y-axis direction). For example, as illustrated in FIG. 4, the second bank layer 125 may include a definition wall extending in the first direction (e.g., y-axis direction). The definition wall of the second bank layer 125 extending in the first direction (e.g., y-axis direction) may overlap the definition wall of the first bank layer 121 extending in the first direction (e.g., y-axis direction). The definition wall of the first bank layer 121 extending in the second direction (e.g., x-axis direction) may be exposed through the second opening 125OP. For example, a portion of the first bank layer 121 positioned between the (1-1)th opening 121OP1 and the (1-2)th opening 121OP2 may be exposed through the line-shaped (2-1)th opening 125OPL1.

The second bank layer 125 may include an organic insulating material. For example, the second bank layer 125 may include an epoxy-based photosensitive resin, an acryl-based photosensitive resin, or a mixture thereof. In an embodiment, the second bank layer 125 may include a positive photosensitive resin. In an embodiment, the second bank layer 125 may include photosensitive polyimide. An upper surface of the second bank layer 125 and an inner side surface of the second bank layer 125 defining the second opening 125OP may have lyophobicity. In an embodiment, a lower surface of the second bank layer 125 may have lyophilicity.

As described above, the position and shape of the pixel may correspond to the position and shape of the emission area defined by the first opening 121OP of the first bank layer 121. For example, a first pixel PX1 may correspond to the (1-1)th opening 121OP1, a second pixel PX2 may correspond to the (1-2)th opening 121OP2, and a third pixel PX3 may correspond to the (1-3)th opening 121OP3.

The first pixel PX1 and the second pixel PX2 may be arranged in the first direction (e.g., y-axis direction) to form a first column, the third pixel PX3 and a fourth pixel PX4 may be arranged in the first direction (e.g., y-axis direction) to form a second column, and a fifth pixel PX5 and a sixth pixel PX6 may be arranged in the first direction (e.g., y-axis direction) to form a third column. Likewise, the first pixel PX1, the third pixel PX3, and the fifth pixel PX5 may be arranged in the second direction (e.g., x-axis direction) to form a first row, and the second pixel PX2, the fourth pixel PX4, and the sixth pixel PX6 may be arranged in the second direction (e.g., x-axis direction) to form a second row.

The pixels arranged in the same column may emit light of the same color. For example, the first pixel PX1 and the second pixel PX2 may emit light of a first color, the third pixel PX3 and the fourth pixel PX4 may emit light of a second color, and the fifth pixel PX5 and the sixth pixel PX6 may emit light of a third color. For example, the first color may be red, the second color may be green, and the third color may be blue. Thus, the pixels arranged in the same column may include the same color light emitting material.

Although FIG. 4 illustrates that the size (or area) of each pixel is equal, the size (or area) of the pixel may be different depending on the color of emitted light. For example, the size (or area) of a pixel emitting green light may be smaller than the size (or area) of a pixel emitting red light or blue light.

Referring to FIGS. 5 and 6, a pixel circuit layer PCL may be disposed over a substrate 100. The pixel circuit layer PCL may include a first transistor TR1, a second transistor TR2, and a third transistor, and a buffer layer 111, a first gate insulating layer 113, a second gate insulating layer 115, an interlayer insulating layer 117, and a planarization layer 119 disposed under and/or over the components of the transistor. For example, the first transistor TR1, the second transistor TR2, and the third transistor may correspond to the first thin film transistor T1 illustrated in FIG. 2. As the structure of the second transistor TR2 and the structure of the third transistor are the same as or similar to the structure of the first transistor TR1, redundant descriptions thereof will be omitted for descriptive convenience.

The buffer layer 111 may include an inorganic insulating material such as silicon nitride (SiNₓ), silicon oxynitride (SiON), or silicon oxide (SiOₓ) and may have a single-layer structure or a multiple-layer structure including the inorganic insulating material. The buffer layer 111 may function to increase the smoothness of the upper surface of the substrate 100 or to prevent or minimize the penetration of impurities into a semiconductor layer Act from the substrate 100 or the like.

The first transistor TR1 may include a semiconductor layer Act, and the semiconductor layer Act may include polysilicon. In another example, the semiconductor layer Act may include amorphous silicon, may include an oxide semiconductor material, or may include an organic semiconductor material.

A gate electrode GE may overlap a portion of the semiconductor layer Act. The gate electrode GE may include a conductive material. The gate electrode GE may include a conductive material such as molybdenum (Mo), aluminum (Al), or titanium (Ti) and may have a single-layer structure or a multiple-layer structure including the above material.

The first gate insulating layer 113 between the semiconductor layer Act and the gate electrode GE may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

The second gate insulating layer 115 may cover the gate electrode GE. For example, the second gate insulating layer 115 may include an inorganic insulating material such as silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

An upper electrode CE2 of a storage capacitor Cst may be disposed over the second gate insulating layer 115. The upper electrode CE2 may overlap the gate electrode GE thereunder. For example, the gate electrode GE and the upper electrode CE2 overlapping each other with the second gate insulating layer 115 therebetween may form the storage capacitor Cst. For example, the gate electrode GE may function as a lower electrode CE1 of the storage capacitor Cst.

For example, the storage capacitor Cst and the first transistor TR1 may be arranged to overlap each other. In some embodiments, the storage capacitor Cst may be arranged not to overlap the first transistor TR1.

The upper electrode CE2 may include a conductive material such as aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), or copper (Cu) and may have a single-layer structure or a multiple-layer structure including the above material.

The interlayer insulating layer 117 may cover the upper electrode CE2. The interlayer insulating layer 117 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The interlayer insulating layer 117 may have a single-layer structure or a multiple-layer structure including the above inorganic insulating material.

Each of a drain electrode SD1 and a source electrode SD2 may be positioned over the interlayer insulating layer 117. Each of the drain electrode SD1 and the source electrode SD2 may be connected (e.g., electrically connected) to the semiconductor layer Act through contact holes formed in the first gate insulating layer 113, the second gate insulating layer 115, and the interlayer insulating layer 117. The drain electrode SD1 and the source electrode SD2 may include a material having high conductivity. The drain electrode SD1 and the source electrode SD2 may include a conductive material such as molybdenum (Mo), aluminum (Al), copper (Cu), or titanium (Ti) and may have a single-layer structure or a multiple-layer structure including the above material. In an embodiment, the drain electrode SD1 and the source electrode SD2 may have a multilayer structure of Ti/Al/Ti. In another example, at least one of the drain electrode SD1 and the source electrode SD2 may be omitted, and a portion of the semiconductor layer Act may be electrically conductive to replace the at least one of the drain electrode SD1 and the source electrode SD2.

The planarization layer 119 may cover the first transistor TR1 and may include a contact hole exposing a portion of the first transistor TR1. The planarization layer 119 may include an organic insulating layer. The planarization layer 119 may include an organic insulating material such as a general-purpose polymer such as polymethylmethacrylate (PMMA) or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, or any combination thereof.

A display element layer DEL may be disposed over the pixel circuit layer PCL. The display element layer DEL may include a first organic light emitting diode OLED1, a second organic light emitting diode OLED2, and a third organic light emitting diode OLED3, and a first bank layer 121, a residual sacrificial layer 123, and a second bank layer 125, which are disposed under and/or over the components of the organic light emitting diode. As the structure of the second organic light emitting diode OLED2 and the structure of the third organic light emitting diode OLED3 are the same as or similar to the structure of the first organic light emitting diode OLED1, redundant descriptions thereof will be omitted for descriptive convenience.

In an embodiment, the first pixel electrode 211 may be disposed over the pixel circuit layer PCL. The first pixel electrode 211 may be electrically connected to the drain electrode SD1 or the source electrode SD2 of the first transistor TR1 through a contact hole penetrating the planarization layer 119. As illustrated in FIGS. 4 and 5, the second pixel electrode 212 may be spaced apart from the first pixel electrode 211 by a certain distance in the first direction (e.g., y-axis direction). As illustrated in FIGS. 4 and 6, the third pixel electrode 213 may be spaced apart from the first pixel electrode 211 by a certain distance in the second direction (e.g., x-axis direction).

The first bank layer 121 may be disposed over the pixel circuit layer PCL. The first bank layer 121 may include a (1-1)th opening 121OP1 exposing a center portion of the first pixel electrode 211, a (1-2)th opening 121OP2 exposing a center portion of the second pixel electrode 212, and a (1-3)th opening 121OP3 exposing a center portion of the third pixel electrode 213. The (1-1)th opening 121OP1 may define an emission area EA1 of the first organic light emitting diode OLED1, the (1-2)th opening 121OP2 may define an emission area EA2 of the second organic light emitting diode OLED2, and the (1-3)th opening 121OP3 may define an emission area EA3 of the third organic light emitting diode OLED3. For example, the first bank layer 121 may prevent an arc or the like from occurring at the edge portion of the pixel electrodes 210 by increasing the distance between the edge portion of the pixel electrodes 210 and an opposite electrode 230.

The first bank layer 121 may have a first thickness t1. The first thickness t1 may be in a range of about 200 nm to about 500 nm.

The second bank layer 125 may be disposed over the first bank layer 121. The second bank layer 125 may include a second opening 125OP overlapping the first opening 121OP and exposing the center portions of the pixel electrodes 210. In an embodiment, the second opening 125OP may have a line shape extending in the first direction (e.g., y-axis direction) as illustrated in FIG. 4.

In this regard, FIGS. 4 to 6 illustrate that a line-shaped (2-1)th opening 125OPL1 exposes the center portions of the first pixel electrode 211 and the second pixel electrode 212 and overlaps the (1-1)th opening 121OP1 and the (1-2)th opening 121OP2. A line-shaped (2-2)th opening 125OPL2 may be spaced apart from the line-shaped (2-1)th opening 125OPL1 by a certain distance in the second direction (e.g., x-axis direction).

As illustrated in FIG. 5, an upper surface 121US1 of the first bank layer 121 may be exposed through the line-shaped (2-1)th opening 125OPL1 between the (1-1)th opening 121OP1 and the (1-2)th opening 121OP2. As illustrated in FIG. 6, the second bank layer 125 may be positioned on an upper surface 121US2 of the first bank layer 121 between the (1-1)th opening 121OP1 and the (1-3)th opening 121OP3.

The second bank layer 125 may have a second thickness t2. The second thickness t2 may be greater than the first thickness t1 and may be a thickness sufficient to separate ink including a light emitting material. For example, the second thickness t2 may be in a range of about 500 nm to about 1 μm.

The residual sacrificial layer 123 may be positioned between the first bank layer 121 and the second bank layer 125. The residual sacrificial layer 123 may be positioned to overlap the second bank layer 125 in a plan view. As the residual sacrificial layer 123 is positioned only in an area overlapping the second bank layer 125, the residual sacrificial layer 123 may have the same or substantially the same pattern as the second bank layer 125 in a plan view. The residual sacrificial layer 123 may include a third opening overlapping the second opening 125OP.

The residual sacrificial layer 123 may include a material removed by a developer such as water or tetramethylammonium hydroxide (TMAH) solution. For example, the residual sacrificial layer 123 may include a tungsten oxide (WOₓ), a molybdenum oxide (MoOₓ), or a mixture thereof.

The boundary area of the first opening 121OP extending in the first direction (e.g., y-axis direction) may overlap the boundary area of the second opening 125OP. For example, as illustrated in FIG. 6, an inner side surface 121SS of the first bank layer 121 defining the first opening 121OP, an inner side surface 123SS of the residual sacrificial layer 123 defining the third opening, and an inner side surface 125SS of the second bank layer 125 defining the second opening 125OP may be continuous connected to each other.

A first emission layer 221 may be disposed over the first pixel electrode 211. For example, the first emission layer 221 may be arranged in the (1-1)th opening 121OP1. In an embodiment, one emission layer may be arranged over pixel electrodes 210 positioned in the same second opening 125OP. For example, as illustrated in FIG. 5, the first emission layer 221 may continuously extend over the first pixel electrode 211 and the second pixel electrode 212 across the upper surface 121US1 of the first bank layer 121 between the (1-1)th opening 121OP1 and the (1-2)th opening 121OP2. The first emission layer 221 may overlap the line-shaped (2-1)th opening 125OPL1.

The first emission layer 221 may include a high-molecular or low-molecular weight organic material for emitting a certain color. For example, the first emission layer 221 may be formed by discharging ink including a light emitting material onto the first pixel electrode 211 and the second pixel electrode 212. For example, the first emission layer 221 may be formed by an inkjet printing process.

For example, the first emission layer 221 may include a first functional layer and/or a second functional layer thereunder and thereover, respectively. For example, the first functional layer may include a hole transport layer (HTL) or may include the hole transport layer (HTL) and a hole injection layer (HIL). The second functional layer may be selectively arranged. The second functional layer may include an electron transport layer (ETL) and/or an electron injection layer (EIL).

The first emission layer 221 may have a concave shape that the thickness of the first emission layer 221 increases as being closer from the center toward the edge portion of the first opening 121OP. A boundary (or side surface) 221BP of the first emission layer 221 in the first direction (e.g., y-axis direction) may be positioned on the inner side surface of the residual sacrificial layer 123 or the inner side surface 121SS of the first bank layer 121 adjacent to the inner side surface of the residual sacrificial layer 123.

A second emission layer 222 may be disposed over the third pixel electrode 213. The second emission layer 222 may overlap the line-shaped (2-2)th opening 125OPL2 and may be spaced apart from the first emission layer 221 by the second bank layer 125 positioned between the (2-1)th opening 125OPL1 and the (2-2)th opening 125OPL2. The first emission layer 221 may include a light emitting material emitting light of the first color, and the second emission layer 222 may include a light emitting material emitting light of the second color. As the second emission layer 222 has the same or similar structure as the first emission layer 221, redundant descriptions thereof will be omitted for descriptive convenience.

The opposite electrode 230 may be arranged to cover the first emission layer 221, the first bank layer 121, and the second bank layer 125. The opposite electrode 230 may include a conductive material having a low work function. For example, the opposite electrode 230 may include a transparent layer (or a semi-transparent layer) including silver (Ag), magnesium (Mg), aluminum (Al), platinum (Pt), palladium (Pd), gold (Au), nickel (Ni), neodymium (Nd), iridium (Jr), chromium (Cr), lithium (Li), calcium (Ca), or any alloy thereof. In another example, the opposite electrode 230 may further include a layer such as ITO, IZO, ZnO, or In₂O₃ on the (semi)transparent layer including the above material.

For example, in an embodiment, a thin film encapsulation layer or an encapsulation substrate may be disposed over the opposite electrode 230.

Embodiments may improve the uniformity of the thickness of the emission layer by adjusting the positions of the first bank layer 121 and the residual sacrificial layer 123. In embodiments, with the inner side surface 123SS of the residual sacrificial layer 123 therebetween, the inner side surface 121SS of the first bank layer 121 may have lyophilicity and the inner side surface 125SS of the second bank layer 125 may have lyophobicity. Thus, in case that ink including a light emitting material is discharged (or injected) to form an emission layer, the boundary (or outer side surface) of the ink including the light emitting material may be positioned on the inner side surface 123SS of the residual sacrificial layer 123 or the inner side surface 121SS of the first bank layer 121 adjacent to the residual sacrificial layer 123. In case that the solvent of the ink including the light emitting material is evaporated by a drying process and thus the volume thereof shrinks, the boundary (or outer side surface) of the ink positioned on the inner side surface 123SS of the residual sacrificial layer 123 or the inner side surface 121SS of the first bank layer 121 adjacent to the residual sacrificial layer 123 may be changed less than the center portion of the ink. Thus, the uniformity of the thickness of the emission layer may be improved by adjusting the positions of the first bank layer 121 and the residual sacrificial layer 123.

For example, as an upper surface 125US of the second bank layer 125 has lyophobicity, the ink including the light emitting material may not overflow onto the upper surface of the second bank layer 125 and the emission layer may be more accurately formed at a desired position.

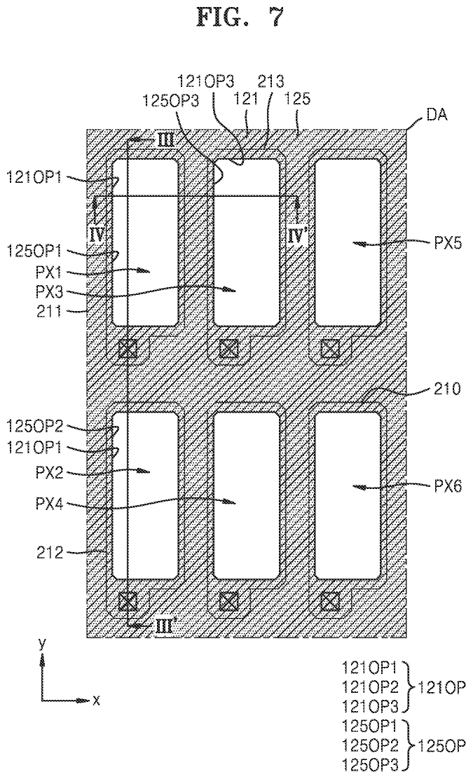

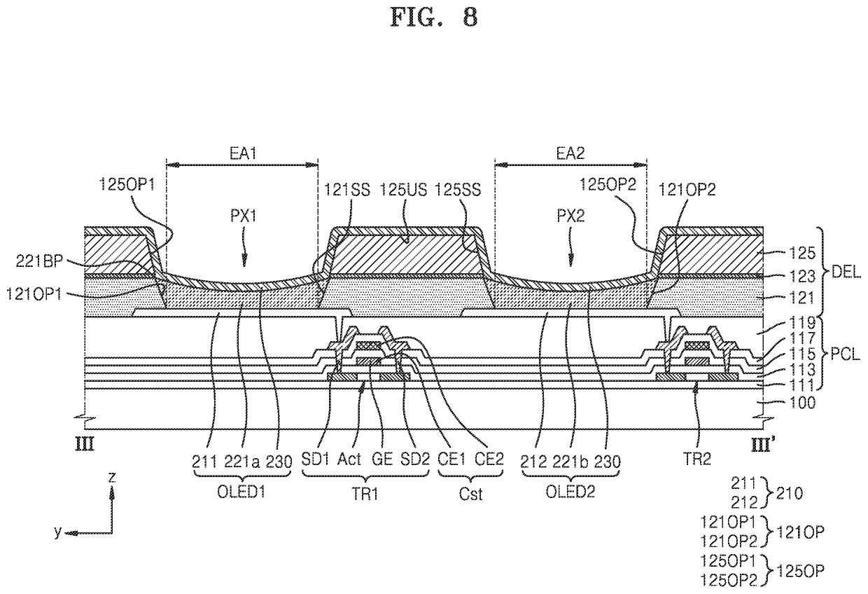

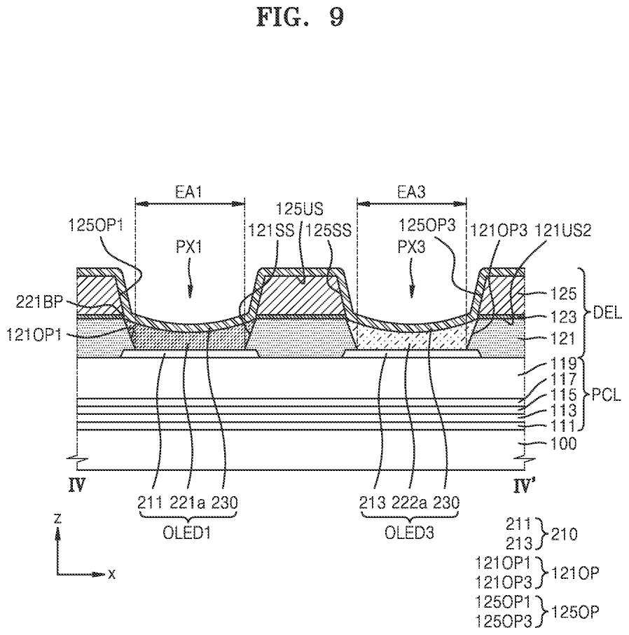

FIG. 7 is a schematic plan view illustrating a display apparatus according to an embodiment, FIG. 8 is a schematic cross-sectional view illustrating a cross-section of the display apparatus taken along line III-III′ in FIG. 7, and FIG. 9 is a schematic cross-sectional view illustrating a cross-section of the display apparatus taken along line IV-IV′ in FIG. 7.

FIG. 7 may be similar to FIG. 5 but may be different from FIG. 5 in that a second bank layer 125 includes a second opening 125OP corresponding to (or overlapping) each first opening 121OP. Hereinafter, for descriptive convenience, redundant descriptions thereof will be omitted and differences therebetween will be described.

Referring to FIG. 7, pixel electrodes 210, which are two-dimensionally arranged on a plane, may be arranged in a display area DA. The pixel electrodes 210 may be spaced apart from each other by a certain distance in a first direction (e.g., y-axis direction) and a second direction (e.g., x-axis direction). For example, a first pixel electrode 211 and a second pixel electrode 212 may be spaced apart from each other by a certain distance in the first direction (e.g., y-axis direction), and the first pixel electrode 211 and a third pixel electrode 213 may be spaced apart from each other by a certain distance in the second direction (e.g., x-axis direction).

A first bank layer 121 may be arranged to cover the edge portion of each of the pixel electrodes 210. For example, the first bank layer 121 may include first openings 121OP exposing a center portion of each of the pixel electrodes 210. The first openings 121OP may be spaced apart from each other by a certain distance in the first direction (e.g., y-axis direction) and the second direction (e.g., x-axis direction) in a plan view, corresponding to (or overlapping) the pixel electrodes 210.

For example, the first bank layer 121 may include a (1-1)th opening 121OP1 exposing a center portion of the first pixel electrode 211, a (1-2)th opening 121OP2 exposing a center portion of the second pixel electrode 212, and a (1-3)th opening 121OP3 exposing a center portion of the third pixel electrode 213. The (1-1)th opening 121OP1 and the (1-2)th opening 121OP2 may be spaced apart from each other by a certain distance in the first direction (e.g., y-axis direction), and the (1-1)th opening 121OP1 and the (1-3)th opening 121OP3 may be spaced apart from each other by a certain distance in the second direction (e.g., x-axis direction).

A second bank layer 125 may be positioned over the first bank layer 121. In an embodiment, the second bank layer 125 may include second openings 125OP exposing the center portions of the pixel electrodes 210 arranged in the first direction (e.g., y-axis direction) and respectively corresponding to (or overlapping) the first openings 121OP. For example, a (2-1)th opening 125OP1 may overlap the (1-1)th opening 121OP1 exposing a center portion of the first pixel electrode 211, a (2-2)th opening 125OP2 may overlap the (1-2)th opening 121OP2 exposing a center portion of the second pixel electrode 212, and a (2-3)th opening 125OP3 may overlap the (1-3)th opening 121OP3 exposing a center portion of the third pixel electrode 213. The (2-1)th opening 125OP1 and the (2-2)th opening 125OP2 may be spaced apart from each other by a certain distance in the first direction (e.g., y-axis direction), and the (2-1)th opening 125OP1 and the (2-3)th opening 125OP3 may be spaced apart from each other by a certain distance in the second direction (e.g., x-axis direction).

In an embodiment, as illustrated in FIG. 7, the second bank layer 125 may have a grid shape in which a definition wall extending in the first direction (e.g., y-axis direction) and a definition wall extending in the second direction (e.g., x-axis direction) intersect each other. In an embodiment, the second bank layer 125 may cover the upper surface of the first bank layer 121.

Referring to FIGS. 8 and 9, the first bank layer 121 may be disposed over the pixel circuit layer PCL. The first bank layer 121 may include a (1-1)th opening 121OP1 exposing a center portion of the first pixel electrode 211, a (1-2)th opening 121OP2 exposing a center portion of the second pixel electrode 212, and a (1-3)th opening 121OP3 exposing a center portion of the third pixel electrode 213. The (1-1)th opening 121OP1 may define an emission area EA1 of the first organic light emitting diode OLED1, the (1-2)th opening 121OP2 may define an emission area EA2 of the second organic light emitting diode OLED2, and the (1-3)th opening 121OP3 may define an emission area EA3 of the third organic light emitting diode OLED3.

The second bank layer 125 may be disposed over the first bank layer 121. The second bank layer 125 may include a second opening 125OP overlapping the first opening 121OP and exposing the center portions of the pixel electrodes 210. A (2-1)th opening 125OP1 may overlap the (1-1)th opening 121OP1 exposing a center portion of the first pixel electrode 211, a (2-2)th opening 125OP2 may overlap the (1-2)th opening 121OP2 exposing a center portion of the second pixel electrode 212, and a (2-3)th opening 125OP3 may overlap the (1-3)th opening 121OP3 exposing a center portion of the third pixel electrode 213.

A residual sacrificial layer 123 may be positioned between the first bank layer 121 and the second bank layer 125. The residual sacrificial layer 123 may be positioned to overlap the second bank layer 125 in a plan view. As the residual sacrificial layer 123 is positioned only in an area overlapping the second bank layer 125, the residual sacrificial layer 123 may have the same or substantially the same pattern as the second bank layer 125 in a plan view. The residual sacrificial layer 123 may include a third opening overlapping the second opening 125OP.

A (1-1)th emission layer 221a may be disposed over the first pixel electrode 211, a (1-2)th emission layer 221b may be disposed over the second pixel electrode 212, and a (2-1)th emission layer 222a may be disposed over the third pixel electrode 213. For example, the (1-1)th emission layer 221a and the (1-2)th emission layer 221b may be spaced apart from each other in the first direction (e.g., y-axis direction) with the first bank layer 121 and the second bank layer 125 therebetween. The (1-1)th emission layer 221a and the (2-1)th emission layer 222a may be spaced apart from each other in the second direction (e.g., x-axis direction) with the first bank layer 121 and the second bank layer 125 therebetween.

Each of the (1-1)th emission layer 221a, the (1-2)th emission layer 221b, and the (2-1)th emission layer 222a may have a concave shape that the thickness of each of the (1-1)th emission layer 221a, the (1-2)th emission layer 221b, and the (2-1)th emission layer 222a increases as being closer from the center toward the edge portion of the first opening 121OP. A boundary (or side surface) 221BP of the (1-1)th emission layer 221a may be positioned on the inner side surface of the residual sacrificial layer 123 or the inner side surface 121SS of the first bank layer 121 adjacent to the inner side surface of the residual sacrificial layer 123.

In an embodiment, as the (1-1)th emission layer 221a and the (1-2)th emission layer 221b are separated by the second bank layer 125, the leakage current between the pixels adjacent to each other in the first direction (e.g., y-axis direction) may be reduced or minimized.

The (1-1)th emission layer 221a and the (1-2)th emission layer 221b may include a light emitting material emitting light of the first color, and the (2-1)th emission layer 222a may include a light emitting material emitting light of the second color.

The opposite electrode 230 may be arranged to cover the first emission layer 221, the first bank layer 121, and the second bank layer 125. For example, in an embodiment, a thin film encapsulation layer or an encapsulation substrate may be disposed over the opposite electrode 230.

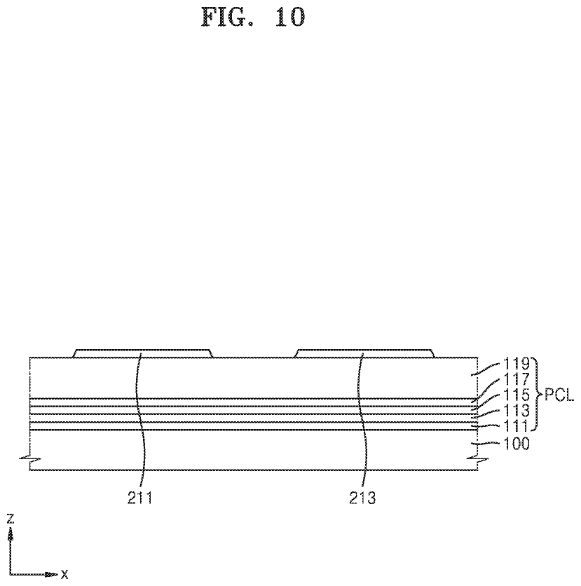

FIGS. 10 to 16 are schematic cross-sectional views sequentially illustrating a method of manufacturing a display apparatus according to an embodiment. FIGS. 10 to 16 sequentially illustrate a method of manufacturing a first pixel PX1 and a third pixel PX3 adjacent to each other in the second direction (e.g., the x-axis direction).

Referring to FIG. 10, a pixel circuit layer PCL including at least one transistor may be formed over a substrate 100, and a first pixel electrode 211 and a third pixel electrode 213 may be formed over the pixel circuit layer PCL.

The upper surfaces of the first pixel electrode 211 and the third pixel electrode 213 may have lyophilicity.

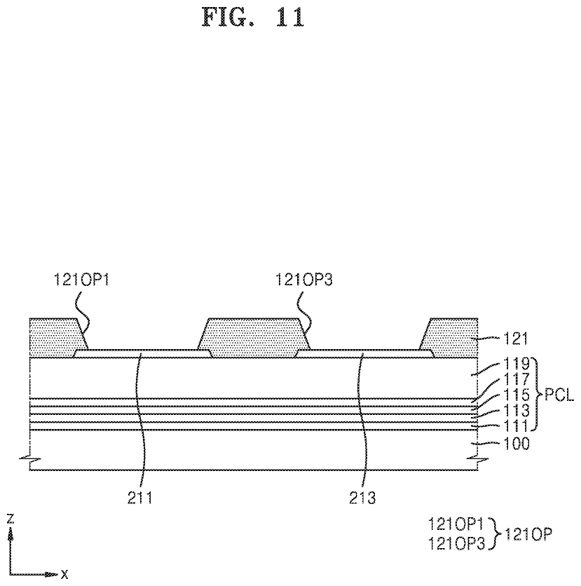

Referring to FIG. 11, a first bank layer 121 may be formed over the pixel circuit layer PCL. The first bank layer 121 may be formed by forming an inorganic insulating material layer or an organic insulating material layer and patterning the (1-1)th opening 121OP1 and the (1-3)th opening 121OP3 such that a center portion of each of the first pixel electrode 211 and the third pixel electrode 213 may be exposed.

In an embodiment, the first bank layer 121 may include silicon oxide (SiOₓ), silicon nitride (SiNₓ), silicon oxynitride (SiON), or the like. In an embodiment, the first bank layer 121 may include an epoxy-based polymer, an acryl-based polymer, or a mixture thereof.

In an embodiment, the first bank layer 121 may be formed to have a first thickness t1. In case that ink including a light emitting material is discharged, the first thickness t1 may be determined based on the position of the boundary (or outer side surface) of the ink. The first thickness t1 may be in a range of about 200 nm to about 500 nm. The upper surface of the first bank layer 121 and the inner side surface 121SS of the first bank layer 121 defining the first opening 121OP may have lyophilicity.

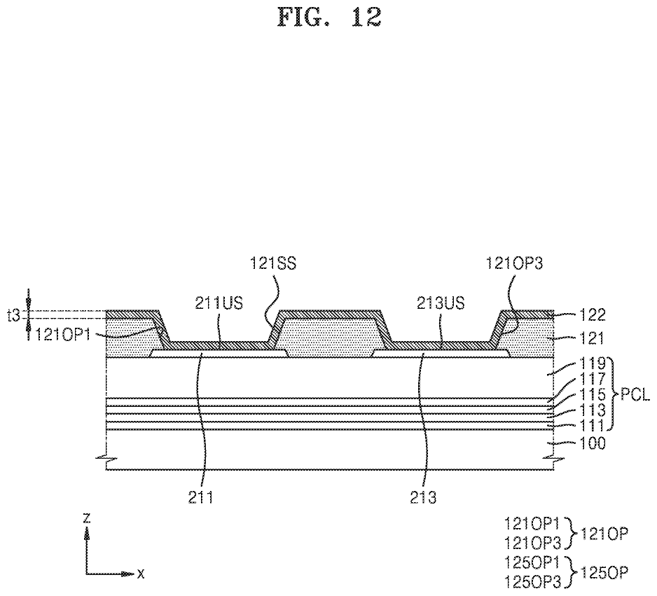

Referring to FIG. 12, a sacrificial layer 122 may be formed to cover the first pixel electrode 211, the third pixel electrode 213, and the first bank layer 121.

In an embodiment, the sacrificial layer 122 may include a material removed by a developer such as water or tetramethylammonium hydroxide (TMAH) solution. For example, the sacrificial layer 122 may include a tungsten oxide (WOₓ), a molybdenum oxide (MoOₓ), or a mixture thereof.

In an embodiment, the sacrificial layer 122 may have a third thickness t3. In an operation of forming a second bank layer 125 described below, the third thickness t3 may be determined based on a thickness by which the sacrificial layer 122 is removed by a developer. For example, the third thickness t3 may be a thickness sufficient such that the sacrificial layer 122 may cover an exposed upper surface 211US of the first pixel electrode 211, and an exposed upper surface 213US of the third pixel electrode 213, and an inner side surface 121SS of the first bank layer 121 even after at least one photolithography process. In an embodiment, the third thickness t3 may be in a range of about 20 nm to about 50 nm.

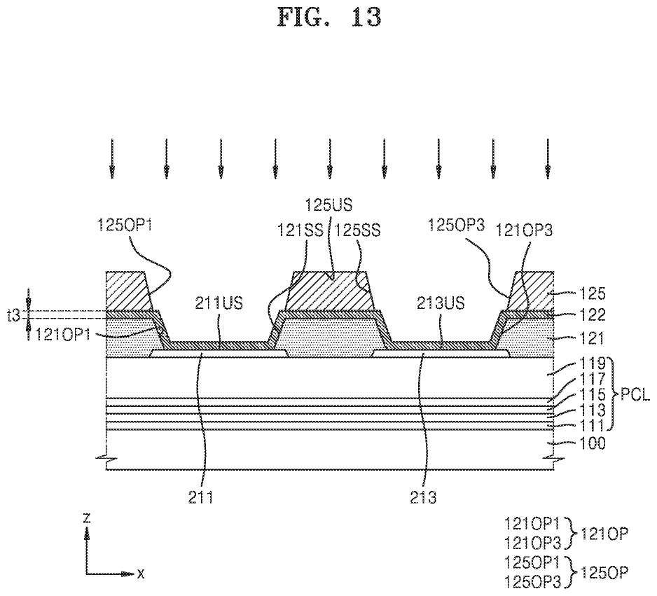

Referring to FIG. 13, a second bank layer 125 may be formed over the sacrificial layer 122. The second bank layer 125 may be formed by forming an organic insulating material layer and patterning the second openings 125OP such that a center portion of each of the first pixel electrode 211 and the third pixel electrode 213 may be exposed.

As described above, in an embodiment, the second openings 125OP may have a line shape extending in the first direction (e.g., y-axis direction). In another example, each of the second openings 125OP may have a shape corresponding to (or overlapping) each first opening 121OP. In this regard, FIG. 13 illustrates that the second bank layer 125 includes a (2-1)th opening 125OP1 corresponding to (or overlapping) the (1-1)th opening 121OP1 and a (2-3)th opening 125OP3 corresponding to (or overlapping) the (1-3)th opening 121OP3.

In an embodiment, the second bank layer 125 may include an epoxy-based photosensitive resin, an acryl-based photosensitive resin, or a mixture thereof. In an embodiment, the second bank layer 125 may include a positive photosensitive resin. In an embodiment, the second bank layer 125 may include photosensitive polyimide. Before plasma treatment, the surface of the second bank layer 125 may have lyophilicity.

The second bank layer 125 may be formed to have a second thickness t2. The second thickness t2 may be greater than the first thickness t1 and may be a thickness sufficient to separate ink including a light emitting material. For example, the second thickness t2 may be in a range of about 500 nm to about 1 μm.

In the process of patterning the (2-1)th opening 125OP1 and the (2-3)th opening 125OP3, a portion of the sacrificial layer 122 may be removed and thus the thickness of the sacrificial layer 122 may decrease. Even after the second bank layer 125 is formed, the sacrificial layer 122 may cover the upper surface 211US of the first pixel electrode 211, the upper surface 213US of the third pixel electrode 213, and the inner side surface 121SS of the first bank layer 121.

A plasma treatment may be performed such that the surface of the second bank layer 125 and the surface of the sacrificial layer 122 exposed through the second opening 125OP may have lyophobicity. In an embodiment, a tetrafluoromethane (CF₄) plasma treatment may be performed on the surface of the second bank layer 125 and the surface of the sacrificial layer 122 exposed through the second opening 125OP.

Through the plasma treatment, the upper surface 125US of the second bank layer 125, the inner side surface 125SS of the second bank layer 125, and the surface of the sacrificial layer 122 exposed through the second opening 125OP may have lyophobicity.

For example, the upper surface 211US of the first pixel electrode 211, the upper surface 213US of the third pixel electrode 213, and the inner side surface 121SS of the first bank layer 121 covered by the sacrificial layer 122 may still have lyophilicity. In an embodiment, the lower surface of the second bank layer 125 may still have lyophilicity.

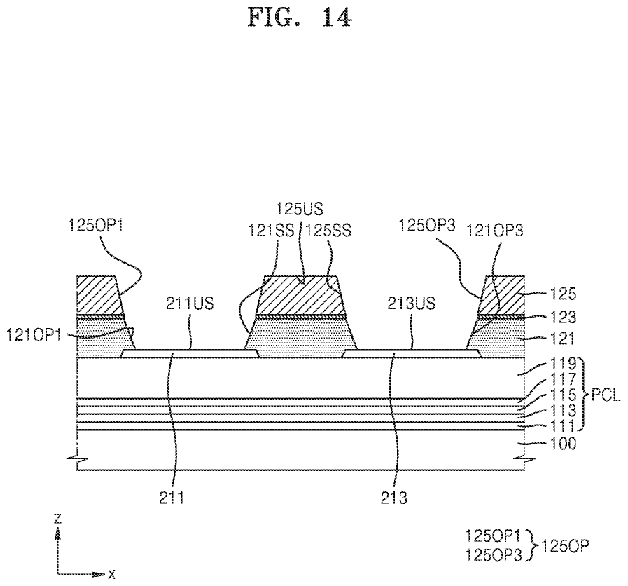

Referring to FIG. 14, a residual sacrificial layer 123 may be formed by removing the sacrificial layer exposed through the second opening 125OP by using a developer. For example, the developer may be water or tetramethylammonium hydroxide (TMAH) solution.

As the residual sacrificial layer 123 remains only in an area covered by the second bank layer 125, the residual sacrificial layer 123 may have the same or substantially the same pattern as the second bank layer 125 in a plan view. The residual sacrificial layer 123 may include a third opening overlapping the second opening 125OP.

The upper surface 211US of the first pixel electrode 211, the upper surface 213US of the third pixel electrode 213, and the inner side surface 121SS of the first bank layer 121 exposed by removing the sacrificial layer may still have lyophilicity.

The inner side surface 121SS of the first bank layer 121 may be continuous with the inner side surface 123SS of the residual sacrificial layer 123 and the inner side surface 125SS of the second bank layer 125. With the inner side surface 123SS of the residual sacrificial layer 123 as a boundary, the inner side surface 121SS of the first bank layer 121 positioned thereunder may have lyophilicity, and the inner side surface 125SS of the second bank layer 125 positioned thereover may have lyophobicity.

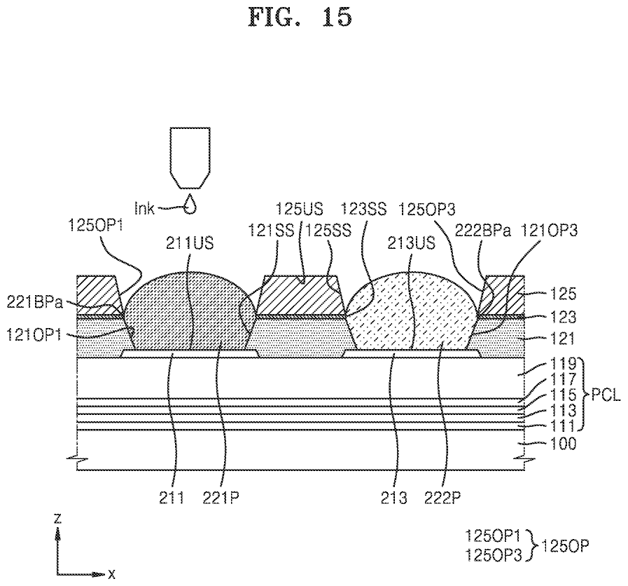

Referring to FIG. 15, by discharging ink including a light emitting material, a first emission layer forming material 221P may be formed over the first pixel electrode 211, and a second emission layer forming material 222P may be formed over the third pixel electrode 213.

In an embodiment, the first emission layer forming material 221P and the second emission layer forming material 222P may be formed by an inkjet printing process.

As the upper surface 211US of the first pixel electrode 211, the upper surface 213US of the third pixel electrode 213, and the inner side surface 121SS of the first bank layer 121 have lyophilicity, the nonuniform application of the first emission layer forming material 221P and the second emission layer forming material 222P may be suppressed or prevented.

As the upper surface 125US of the second bank layer 125 has lyophobicity, the first emission layer forming material 221P and the second emission layer forming material 222P may not be formed on the upper surface 125US of the second bank layer 125. Thus, even in a high-resolution display apparatus, the emission layer may be more accurately formed at a desired position.

In an embodiment, the first emission layer forming material 221P and the second emission layer forming material 222P may have a convex shape with a thick center portion based on the surface tension and the volume shrinkage after drying.

As described above, the inner side surface 121SS of the first bank layer 121 may have lyophilicity, and the inner side surface 125SS of the second bank layer 125 may have lyophobicity. Thus, a boundary (or side surface) 221BPa of the first emission layer forming material 221P and a boundary (or side surface) 222BPa of the second emission layer forming material 222P may be positioned on the inner side surface 123SS of the residual sacrificial layer 123 or the inner side surface 121SS of the first bank layer 121 adjacent to the residual sacrificial layer 123.

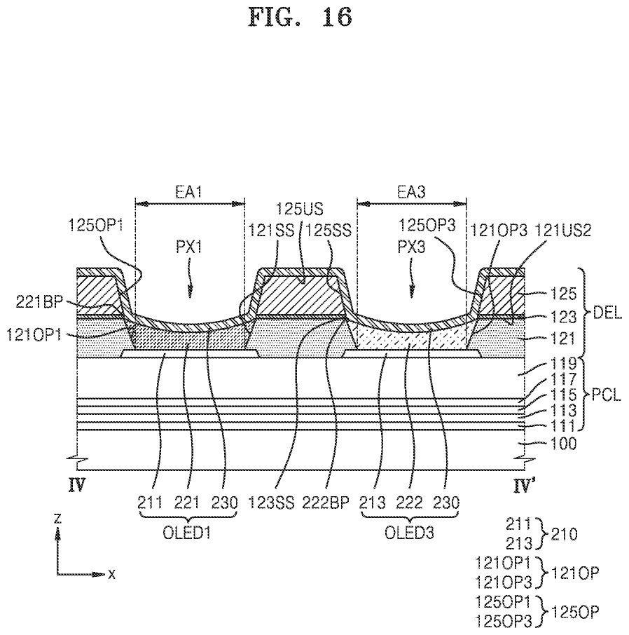

Referring to FIG. 16, a first emission layer 221 and a second emission layer 222 may be formed by drying the first emission layer forming material 221P and the second emission layer forming material 222P.

As the upper surface 211US of the first pixel electrode 211, the upper surface 213US of the third pixel electrode 213, and the inner side surface 121SS of the first bank layer 121 have lyophilicity, the nonuniform formation of the first emission layer 221 and the second emission layer 222 in the drying process may be suppressed or prevented.

As the solvent of the ink including the light emitting material is evaporated, each of the first emission layer 221 and the second emission layer 222 may have a concave shape that the thickness of each of the first emission layer 221 and the second emission layer 222 increases as being closer from the center toward the edge portion of the first opening 121OP.

For example, the position of the boundary area of the emission layer forming material may not change significantly even after the drying process. Thus, a boundary (or side surface) 221BP of the first emission layer 221 and a boundary (or side surface) 222B of the second emission layer 222 may be positioned on the inner side surface 123SS of the residual sacrificial layer 123 or the inner side surface 121SS of the first bank layer 121 adjacent to the residual sacrificial layer 123.

Thereafter, an opposite electrode 230 may be formed over the second bank layer 125, the first emission layer 221, and the second emission layer 222. The opposite electrode 230 may be formed (e.g., integrally formed) to cover the entire surface of the substrate 100.

In embodiments, by performing a plasma treatment by using the sacrificial layer 122, lyophobicity may be selectively formed onto the surface of the second bank layer 125. The second bank layer 125 may be formed of a lyophilic material. For example, the second bank layer 125 may be formed of a positive photosensitive resin. In case that the second bank layer 125 includes photosensitive polyimide, in case that a drop of methylbenzonate solution is dropped on the surface of the second bank layer 125 before a plasma treatment, a contact angle of the solution may be about 4.7°. After a tetrafluoromethane (CF₄) plasma treatment, a contact angle between the surface of the second bank layer 125 and the methylbenzoate solution may be about 64.4° or more. Even after cleaning by using water, the contact angle between the surface of the second bank layer 125 and the methylbenzoate solution may be about 63.0°.

The upper surface 211US of the first pixel electrode 211 and the upper surface 213US of the third pixel electrode 213 may have lyophilicity. In case that the upper surface 211US of the first pixel electrode 211 and the upper surface 213US of the third pixel electrode 213 are formed of an ITO layer, the contact angle of the methylbenzoate solution may be about 4.6°. As a comparative example, in case that a plasma treatment is performed without forming a sacrificial layer, the contact angle between the upper surface of the first pixel electrode and the upper surface of the third pixel electrode and the methylbenzoate solution may be about 15.1° or more. Even after cleaning by using water, the contact angle between the upper surface of the first pixel electrode and the upper surface of the third pixel electrode and the methylbenzoate solution may be about 12.4°. For example, the ink including the light emitting material may not be uniformly applied to the upper surface of the first pixel electrode and the upper surface of the third pixel electrode.

In case that the thickness difference between the center portion and the outside portion of the emission layer is great, light may be not extracted from the outside of the emission layer and thus the emission area may be reduced. According to embodiments, by using a plasma treatment applying the sacrificial layer 122, by selectively forming lyophobicity to the upper surface 125US of the second bank layer 125 and the inner side surface 125SS of the second bank layer 125, the uniformity of the thickness of the emission layer may be improved.

According to an embodiment described above, it is possible to implement a display apparatus for displaying a high-quality image by being improved in the thickness uniformity of an emission layer and a method of manufacturing the display apparatus. However, the scope of the disclosure is not limited to these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a display element including a pixel electrode, an emission layer including a light emitting material, and an opposite electrode;
a first bank layer including a first opening exposing a center portion of the pixel electrode;
a second bank layer disposed over the first bank layer and including a second opening overlapping the first opening; and
a residual sacrificial layer disposed between the first bank layer and the second bank layer and overlapping the second bank layer,
wherein an upper surface of the second bank layer and an inner side surface of the second bank layer defining the second opening have lyophobicity.

2. The display apparatus of claim 1, wherein
an inner side surface of the residual sacrificial layer is disposed between an inner side surface of the first bank layer defining the first opening and the inner side surface of the second bank layer defining the second opening, and
a boundary area of the emission layer is disposed on the inner side surface of the residual sacrificial layer or the inner side surface of the first bank layer adjacent to the inner side surface of the residual sacrificial layer.

3. The display apparatus of claim 1, wherein the inner side surface of the first bank layer has lyophilicity.

4. The display apparatus of claim 1, wherein an upper surface of the pixel electrode has lyophilicity.

5. The display apparatus of claim 1, wherein a lower surface of the second bank layer contacting the residual sacrificial layer has lyophilicity.

6. The display apparatus of claim 1, wherein
the pixel electrode includes a plurality of pixel electrodes spaced apart from each other in a first direction,
the first opening includes a plurality of first openings respectively overlapping the plurality of pixel electrodes, and
the second opening has a line shape extending in the first direction to overlap the plurality of first openings.

7. The display apparatus of claim 6, wherein the emission layer continuously extends in the first direction.

8. The display apparatus of claim 1, wherein
the pixel electrode includes a plurality of pixel electrodes spaced apart from each other in a first direction, and
the first opening and the second opening include a plurality of first openings and a plurality of second openings respectively overlapping the plurality of pixel electrodes.

9. The display apparatus of claim 8, wherein the emission layer includes a plurality of emission layers respectively overlapping the plurality of pixel electrodes.

10. The display apparatus of claim 1, wherein a thickness of the first bank layer is in a range of about 200 nm to about 500 nm.

11. The display apparatus of claim 1, wherein a thickness of the second bank layer is in a range of about 500 nm to about 1 μm.

12. The display apparatus of claim 1, wherein the residual sacrificial layer includes a tungsten oxide (WOₓ), a molybdenum oxide (MoOₓ), or a mixture thereof.

13. A method of manufacturing a display apparatus, the method comprising:
forming a pixel electrode over a substrate;
forming a first bank layer including a first opening exposing a center portion of the pixel electrode;
forming a sacrificial layer on the first bank layer;
forming a second bank layer including a second opening overlapping the first opening on the sacrificial layer;
performing a plasma treatment on a front surface of the substrate where the second bank layer is disposed;
forming a residual sacrificial layer by removing the sacrificial layer exposed through the second opening; and
forming an emission layer by discharging ink including a light emitting material onto the pixel electrode.

14. The method of claim 13, wherein
an inner side surface of the residual sacrificial layer is disposed between an inner side surface of the first bank layer defining the first opening and an inner side surface of the second bank layer defining the second opening, and
an outer side surface of the ink including the light emitting material is disposed on the inner side surface of the residual sacrificial layer or the inner side surface of the first bank layer adjacent to the inner side surface of the residual sacrificial layer.

15. The method of claim 13, wherein in the performing of the plasma treatment, an upper surface of the second bank layer, an inner side surface of the second bank layer, and an upper surface of the sacrificial layer exposed through the second opening have lyophobicity.

16. The method of claim 13, wherein the sacrificial layer includes a tungsten oxide (WOₓ), a molybdenum oxide (MoOₓ), or a mixture thereof.

17. The method of claim 16, wherein a thickness of the sacrificial layer is in a range of about 20 nm to about 50 nm.

18. The method of claim 13, wherein an inner side surface of the first bank layer and an upper surface of the pixel electrode have lyophilicity.

19. The method of claim 13, wherein
the pixel electrode includes a plurality of pixel electrodes spaced apart from each other in a first direction,
the first opening includes a plurality of first openings respectively overlapping the plurality of pixel electrodes, and
the second opening has a line shape extending in the first direction to overlap the plurality of first openings.

20. The method of claim 19, wherein in the forming of the emission layer, the ink including the light emitting material is discharged in the first direction, and the emission layer continuously extends in the first direction.

21. The method of claim 13, wherein
the pixel electrode includes a plurality of pixel electrodes spaced apart from each other in a first direction, and
the first opening and the second opening include a plurality of first openings and a plurality of second openings respectively overlapping the plurality of pixel electrodes.

22. The method of claim 21, wherein in the forming of the emission layer, the emission layer includes a plurality of emission layers respectively overlapping the plurality of pixel electrodes.
